(19) United States
(12) Patent Application Publication
(10) Pub. No.: US 2019/0077275 A1
(43) Pub. Date: Mar. 14, 2019

(54) DYNAMIC COOLING CONTROL FOR BATTERY SYSTEMS

(71) Applicant: SF Motors, Inc., Santa Clara, CA (US)

(72) Inventors: Nathalie Capati, Santa Clara, CA (US); Duanyang Wang, Santa Clara, CA (US); Jacob Heth, Santa Clara, CA (US); Binbin Chi, Santa Clara, CA (US)

(21) Appl. No.: 16/118,358

(22) Filed: Aug. 30, 2018

Related U.S. Application Data
(60) Provisional application No. 62/557,685, filed on Sep. 12, 2017.

(51) Int. Cl. B60L 11/18; H05K 7/20; H01M 10/42; H01M 10/625; H01M 10/613; H01M 10/6554; H01M 10/6568; H01M 10/6556

(52) U.S. Cl. CPC B60L 11/1874; H05K 7/20872; H05K 7/20272; H01M 10/425; G07C 5/08; H01M 10/613; H01M 10/6554; H01M 10/6568; H01M 10/6556; H01M 10/625

(57) ABSTRACT

Systems and methods of controlling temperature in energy storage units. The system can include energy storage units disposed in an electric vehicle. The system can include cold plates disposed in the electric vehicle. Each cold plate can be thermally coupled with an energy storage unit to transfer heat using a coolant. Each cold plate can have an inlet to receive the coolant from an inlet manifold, an outlet to release liquid to an outlet manifold, and a control valve coupled to at least one of the inlet and the outlet. The system can include a battery management system (BMS) connected with the energy storage units. The BMS can determine, for each cold plate, a target flow rate for the coolant using a characteristic of the energy storage unit. The BMS can send, to each cold plate, a signal to control the control valve in accordance with the target flow rate.

### CROSS REFERENCES TO RELATED APPLICATIONS

This application claims priority under 35 U.S.C. § 119(e) to U.S. Provisional Application No. 62/557,685, titled “DYNAMIC COOLING CONTROL FOR BATTERY SYSTEMS,” filed Sep. 12, 2017, which is incorporated by reference in its entirety.

### BACKGROUND

There is an increasing demand for reliable and higher capacity battery cells for high power, higher performance battery packs, to support applications in plug-in hybrid electrical vehicles (PHEVs), hybrid electrical vehicles (HEVs), or electrical vehicle (EV) systems, for example. The temperature of battery pack modules can change under various operating conditions.

### SUMMARY

The present disclosure is directed to battery management units (BMUs) for battery modules in electric vehicles. Each battery module can be thermally coupled with a cold plate. Based on measurements of characteristics of the battery modules, the BMU can control a flow of coolant into and out of the cold plates to regulate temperature of the battery modules.

At least one aspect is directed to a system to control temperature in energy storage units in electric vehicles. The system can include a plurality of energy storage units disposed in an electric vehicle to power the electric vehicle. The system can include a plurality of cold plates disposed in the electric vehicle and connected in parallel to an inlet manifold and an outlet manifold. Each cold plate can be thermally coupled with an energy storage unit of the plurality of energy storage units to transfer heat away from the energy storage unit using a coolant. Each cold plate can have an inlet to receive the coolant from the inlet manifold to enter the cold plate, an outlet to release liquid from the cold plate to the outlet manifold, and at least one control valve coupled to at least one of the inlet and the outlet. The system can include a battery management system (BMS) connected with the plurality of energy storage units and to the at least one control valve of each of the plurality of cold plates. The BMS can receive, for each energy storage unit, an input signal indicative of a characteristic of the energy storage unit. The BMS can determine, for each cold plate, a target flow rate for the coolant through at least one of the inlet and the outlet in accordance with the characteristic of the energy storage unit thermally coupled with the cold plate. The BMS can send, to each cold plate, at least one signal to control the at least one control valve of the cold plate in accordance with the target flow rate of the coolant.

At least one aspect is directed to a method of controlling temperature in energy storage units in electric vehicles. The method can include providing a temperature control system in an electric vehicle. The temperature control system can include a plurality of energy storage units disposed in an electric vehicle to power the electric vehicle. The temperature control system can include a plurality of cold plates disposed in the electric vehicle and connected in parallel to an inlet manifold and an outlet manifold. Each cold plate can be thermally coupled with an energy storage unit of the plurality of energy storage units to transfer heat away from the energy storage unit using a coolant. Each cold plate can have an inlet to receive the coolant from the inlet manifold to enter the cold plate, an outlet to release liquid from the cold plate to the outlet manifold, and at least one control valve coupled to at least one of the inlet and the outlet. The temperature control system can include a battery management system (BMS) connected with the plurality of energy storage units and to the at least one control valve of each of the plurality of cold plates. The BMS can receive, for each energy storage unit, an input signal indicative of a characteristic of the energy storage unit. The BMS can determine, for each cold plate, a flow rate for the coolant through at least one of the inlet and the outlet in accordance with the characteristic of the energy storage unit thermally coupled with the cold plate. The BMS can send, to each cold plate, at least one control signal to control the at least one control valve of the cold plate in accordance with the target flow rate of the coolant determined for the cold plate.

At least one aspect is directed to an electric vehicle. The electric vehicle can include one or more components. The electric vehicle can include a plurality of energy storage units disposed to power the one or more components. The electric vehicle can include a plurality of cold plates disposed in the electric vehicle. Each cold plate can be thermally coupled with an energy storage unit of the plurality of energy storage units to transfer heat away from the energy storage unit using a coolant. Each cold plate can have an inlet to receive the coolant from an inlet manifold to enter the cold plate, an outlet to release liquid from the cold plate to an outlet manifold, and at least one control valve coupled to at least one of the inlet and the outlet. The electric vehicle can include a battery management system (BMS) connected with the plurality of energy storage units and to the at least one control valve of each of the plurality of cold plates. The BMS can receive, for each energy storage unit, an input signal indicative of a characteristic of the energy storage unit. The BMS can determine, for each cold plate, a target flow rate for the coolant through at least one of the inlet and the outlet in accordance with the characteristic of the energy storage unit thermally coupled with the cold plate. The BMS can send, to each cold plate, at least one control signal to control the at least one control valve of the cold plate in accordance with the flow rate of the coolant determined for the cold plate.

### BRIEF DESCRIPTION OF THE DRAWINGS

The accompanying drawings are not necessarily intended to be drawn to scale. Like reference numbers and designations in the various drawings indicate like elements. For purposes of clarity, not every component may be labelled in every drawing. In the drawings:

FIG. 1 depicts an example isometric view of an illustrative embodiment of a temperature control system for an energy storage system;

FIG. 2 depicts an example overhead view of an illustrative embodiment of a system for controlling temperature in an energy storage system;

FIG. 3 a block diagram depicting a cross-sectional view of an illustrative embodiment of an electric vehicle installed with a battery pack;

FIG. 4 depicts an example flow diagram for an illustrative embodiment of a method of controlling temperature in an energy storage unit;

FIG. 5 depicts an example flow diagram for an illustrative embodiment of a method of controlling temperature in an energy storage unit; and

FIG. 6 depicts a block diagram illustrating an architecture for a computer system that can be employed to implement elements of the systems and methods described and illustrated herein.

### DETAILED DESCRIPTION

Following below are more detailed descriptions of various concepts related to, and implementations of, methods, apparatuses, devices, and systems of temperature control systems for battery packs or other energy storage units or systems. The various concepts introduced above and discussed in greater detail below may be implemented in any of numerous ways.

Described herein are temperature control systems for battery packs in electric vehicles for an automotive configuration. An automotive configuration includes a configuration, arrangement or network of electrical, electronic, mechanical or electromechanical devices within a vehicle of any type. An automotive configuration can include battery cells for battery packs in electric vehicles (EVs). EVs can include electric automobiles, cars, motorcycles, scooters, passenger vehicles, passenger or commercial trucks, and other vehicles such as sea or air transport vehicles, planes, helicopters, submarines, boats, or drones. EVs can be fully autonomous, partially autonomous, or unmanned. EVs can include various components that run on electrical power. These various components can include an electric engine, an entertainment system (e.g., a radio, display screen, and sound system), on-board diagnostics system, and electric control units (ECUs) (e.g., an engine control module, a transmission control module, a brake control module, and a body control module), among other components.

Multiple energy storage units (e.g., individual battery cells, submodules, or battery modules, or battery packs each with cells) can be installed in EVs to supply these various components with electrical power. The energy storage units may be located within one area of the EV, for example, next to one another along the bottom chassis of the EV. To achieve proper operation, high-performance, and long life, the energy storage units can be maintained in a temperature-controlled environment. One approach to protect against degradation and overheating can include cooling strips added to side walls of the energy storage units. Once inserted or added to the sidewalls, the cooling strips can draw or evacuate heat from the energy storage unit. Another approach to prevent damage from heat can involve integrating cooling floors (e.g., a fan or heat sink) onto a bottom of energy storage units. The cooling floor can extend or expand a surface area through which heat can dissipate from the energy storage unit.

In both these approaches, however, the hardware components and infrastructure for the temperature control systems may not be modularized to an individual energy storage unit. The lack of modularity in regulating the temperature or heat of the energy storage units can lead to a number of performance-related problems. For one, the temperature control systems may not be readily replaceable or serviceable without disassembling or replacing the entire energy storage unit. Inability to readily replace or service without disassembly can result in effectively limiting the integrity of the energy storage unit. For another, while the two approaches may maintain the energy storage units in nominal, operational temperatures, these may not be able to individually account for different performance levels exhibited across the various energy storage units. For example, there may only be a single inlet valve and outlet valve to control flow of coolant for all the energy storage units in these two approaches. This may lead to excessive consumption of power to address an issue affecting just one or few of the energy storage units, but not other energy storage units. The lack of individual control may be exacerbated in a catastrophic failure event originating from one energy storage unit, such as ignition, fire, and explosion. If the thermal runaway condition is not contained, the thermal propagation may occur between adjacent battery modules or between different battery cells of the same battery module. This can cause an overheating or thermal runaway condition to spillover to the adjacent battery cells or battery modules, potentially resulting in a catastrophic breakdown of the entire energy storage system or battery pack. In EVs, the runaway effect may also lead to failure in other electric components.

To address the drawbacks of these approaches in controlling temperature across energy storage units, a temperature control system can include a modularly replaceable cold plate, sensors to measure characteristics of the energy storage units, and a battery management unit (BMU). The cold plates can be added to each electrical storage unit (e.g., battery module), and later removed and replaced from the energy storage units with the other cold plates remaining in position. The cold plates can be connected in parallel through a central manifold. The central manifold can convey coolant to each cold plate, and can be enclosed in or along a midsection portion of a cluster of the energy storage units. Each cold plate can include an inlet valve to receive coolant from the central manifold to cool the energy storage unit and can include an outlet valve to release liquids from the cold plate to the central manifold. The sensors can be integrated or added to the energy storage units to measure various characteristics of the energy storage unit, such as temperature, pressure, and gas emissions. Based on the measurements of the characteristics of each individual energy storage unit, the BMU can determine a target rate of flow of coolant for channeling through the energy storage unit. The BMU can adjust the inlet control valve of each energy storage unit in accordance with the determined rate of flow. In this manner, the BMU can individually regulate temperature of each individual energy storage unit. As such, the BMU can limit or isolate effects of a thermal runaway condition affecting one of the battery packs to just the affected battery packs, thereby preventing the effect from spreading to other battery packs

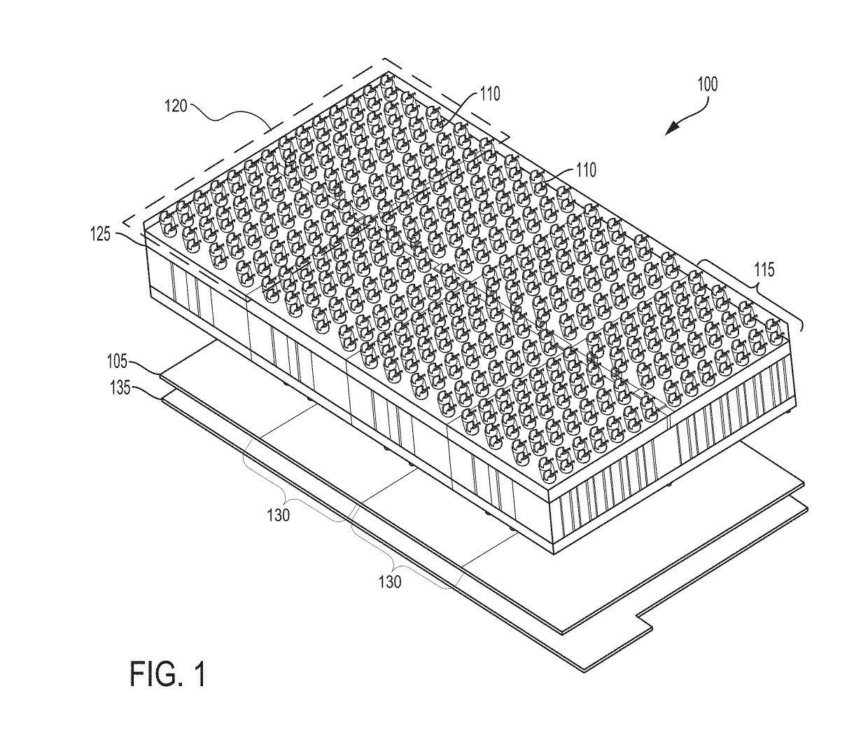

FIG. 1 depicts an example isometric view of an illustrative embodiment of a temperature control system 100 for an energy storage system. The system 100 can include a set of battery cells 110 to store and to provide electrical energy. The battery cells 110 can include a lithium-air battery cell, a lithium ion battery cell, a nickel-zinc battery cell, a zinc-bromine battery cell, a zinc-cerium battery cell, a sodium-sulfur battery cell, a molten salt battery cell, a nickel-cadmium battery cell, or a nickel-metal hydride battery cell, among others. The battery cell 110 can have or define a positive terminal and a negative terminal. Both the positive terminal and the negative terminal can be along a top surface of the battery cell 110. The top surface of the battery cell 110 can be exposed (e.g., to air). A shape of the battery cell 110 can be a prismatic casing with a polygonal base, such as a triangle, square, a rectangular, a pentagon, or a hexagon. The shape of the battery cell 110 can also be cylindrical casing or cylindrical cell with a circular (e.g., as depicted), ovular, or elliptical base, among others. A height of each battery cell 115 can be 60 mm to 100 mm. A width or diameter of each battery cell 115 can be 16 mm to 30 mm. A length of each battery cell 115 can be 16 mm to 30 mm. Each battery cell 115 can have an output of 2V to 4V.

The system 100 can include at least one battery block 115 (sometimes referred herein as an energy storage unit). A set of battery cells 110 can form a battery block 115. The battery block 115 can support or include at least one battery cell 110. Each battery block 115 can define or include one or more holders. Each holder can contain, support, or house at least one of the battery cells 110. The battery block 115 can include electrically insulating, but thermally conductive material around the holder for the battery cells 110. Examples of thermally conductive material for the battery block 115 can include a ceramic material (e.g., silicon nitride, silicon carbide, titanium carbide, zirconium dioxide, and beryllium oxide) and a thermoplastic material (e.g., acrylic glass, polyethylene, polypropylene, polystyrene, or polyvinyl chloride), among others. The battery block 115 can have or define a positive terminal and a negative terminal. The positive terminal for the battery block 115 can correspond to or can be electrically coupled with the positive terminals of the set of battery cells 110 in the battery block 115. The negative terminal for the battery block 115 can correspond to or can be electrically coupled with the negative terminals of the set of battery cells 110 in the battery block 115. Both the positive terminal and the negative terminal of the battery block 115 can be defined or located along a top surface of the battery block 115. The top surface of the battery block 115 can be exposed (e.g., to air). A shape of the battery block 115 can be a prismatic casing with a polygonal base, such as a triangle, a square, a rectangular (e.g., as depicted), a pentagon, or a hexagon, among others. The shape of the battery block 115 can include a cylindrical casing or cylindrical cell with a circular, ovular, or elliptical base, among others. The shapes of the battery blocks 115 can vary from one another. A height of each battery block 115 can be 65 m to 100 mm. A width or diameter of each battery block 115 can be 150 mm to 170 mm. A length of each battery block 115 can be 150 mm to 170 mm. The voltage outputted by the battery cells 110 of the battery block 115 can range 2V to 450V.

The system can include at least one module 125 battery module 125. A set of battery blocks 115 can form the battery module 125. At least two of the battery blocks 115 of the battery module 125 can form or can define a battery submodule 120. The module 125 can include at least one of the battery blocks 115. Each battery block 115 of the battery module 125 can be disposed or arranged next to one another. The arrangement of the battery blocks 115 in the battery module 125 can be in parallel (e.g., as depicted) or in series, or any combination thereof. To form the battery module 125, the battery blocks 115 can be fastened, attached, or otherwise joined to one another. For example, a side wall of the battery blocks 115 can include interlocking joints to attach one battery block 115 to another battery block 115 to form the battery module 125. In addition, the set of battery blocks 115 can be attached to one another using a fastener element, such as a screw, a bolt, a clasp, a bucket, a tie, or a clip, among others. The battery module 125 module 125 can have or define a positive terminal and a negative terminal. The positive terminal for the battery module 125 can correspond to or can be electrically coupled with the positive terminals of the set of battery cells 110 in the battery module 125 across the battery blocks 115. The negative terminal for the battery block 115 can correspond to or can be electrically coupled with the negative terminals of the set of battery cells 110 in the battery module 125 across the battery blocks 115. Both the positive terminal and the negative terminal of the battery module 125 can be defined or located along a top surface of the battery module 125. An overall shape of the battery module 125 can depend on the arrangement and the individual shapes of the battery blocks 115. The dimensions of the battery module 125 can be a multiple of the dimensions of the battery blocks 115 (e.g., 8×1). A height of the battery module 125 can be 65 m to 100 mm. A width or diameter of the battery module 125 can be 100 mm to 330 mm. A length of the battery module 125 can be 160 mm to 1400 mm. For example, when the battery module 125 includes two battery blocks 115, the length can be 160 mm and the width can be 700 mm. When the battery module 125 includes eight battery blocks 115 in series, the length can be 1400 mm and the width can be 330 mm.

The system 100 can include a set of cold plates 105. The cold plate 105 can include a top layer and a bottom layer. Each battery block 115 can be thermally coupled with at least one cold plate 105. Conversely, at least one cold plate 105 can be thermally coupled with at least one of the battery blocks 115, at least one of the submodules 120, or at least one of the battery modules 125. The cold plate 105 can be divided into one or more portions 130. Each portion 130 can be thermally coupled to a corresponding battery block 115 or a corresponding submodule 120 (e.g., as depicted). To thermally couple a cold plate 105 with a battery module 125, the cold plate 105 can be positioned, arranged, or disposed adjacent or below the battery block 115 and the battery module 125. The cold plates 105 and the portions 130 thereof can be arranged or disposed coplanar on the same plane or substantially the same plane (e.g., deviation of between 0° to 15° in inclination or declination and offset between 0 to 10 cm). In this manner, arrangement of the cold plates 105 and the portions 130 onto the battery module 125 can be simplified. At least the top layer can be in contact with or flush with at least a portion of the bottom surface of the battery block 115 or the battery module 125. Conversely, at least the bottom surface of the battery block 115 or the battery module 125 can be in contact or flush with at least a portion of the top layer of the cold plate 105. For example, as depicted in FIG. 1, the cold plate 105 can be arranged below the battery block 115, such that the bottom surface of the battery block 115 lies on the top layer of the cold plate 105. At least the top layer of the cold plate 105 can be thermally coupled with the bottom surface of the battery block 115. The top layer of the cold plate 105 can be connected and thermally coupled with the bottom layer of the cold plate 105. In this manner, the bottom surface of the battery block 115 thermally coupled with the cold plate 105 can be opposite of the top surface of the battery block 115 defining both the positive terminal and the negative terminal. The bottom layer of the cold plate 105 can be thermally coupled with at least the bottom surface of the battery block 115 via the top layer.

Within the cold plate 105, the bottom layer can include or define a receptacle to hold coolant to cool the temperature of the battery block 115 thermally coupled with the battery block 115. The receptacle of the bottom layer can correspond to a hollow structure defined between the top layer and the bottom layer. The receptacle of the bottom layer can include, for example, a channel spanning a top surface of the bottom layer. The channel can have a relatively straight path or a circuitous path (e.g., a zig-zag pattern) across the top surface to distribute coolant across the bottom layer. In some example implementations, the cold plate 105 can have multiple channels, one for each portion 130 of the cold plate 105. The cold plate 105 can receive coolant via an inlet valve and release liquid via an outlet valve. The dimensions of the cold plates 105 can vary relative to dimensions of the battery block 115, the submodule 120 or the battery module 125 as well as the valves to connect to a manifold to receive and release coolant. For example the size of the cold plate 105 can match a floor footprint of the battery block 115 or the battery module 125. The thickness of the cold plate 105 can be 10 mm to 200 mm. The width of the cold plate 105 can be 300 mm to 700 mm. The length of the cold plate 105 can be 300 mm to 700 mm. The functionalities of the cold plate 105 in cooling the battery blocks 115 of the battery module 125 from heat generated by at least some of the battery cells 110 are detailed herein below.

The cold plate 105 can be removably attached, fastened, joined, or otherwise added to the bottom surface of the battery block 115 or the battery module 125. The top layer of the cold plate 105 can define or include one or more holes to insert and secure a fastener element, such as a screw, bolt, a clasp, buckle, tie, or clip, among others. The bottom layer of the cold plate 105 can also define or include one or more holes to insert and secure the fastener element. The bottom surface of the battery block 115 (or the battery module 125) can also define or include one or more holes to insert and secure the fastener element. The holes of the bottom surface of the battery block 115 can align with the holes of the top layer of the cold plate 105. The holes of the top layer of the cold plate 105 can align with the holes of the bottom layer of the cold plate 105. Once aligned, the fastener element can be inserted through the hole of the top layer and the hole of the bottom surface to attach the cold plate 105 to the bottom surface of the battery block 115. The fastener element can also be inserted through the hole of the bottom layer prior to insertion through the hole of the top layer and the hole of the bottom surface 145. For example, the cold plate 105 can be screwed onto the bottom surface of the battery block 115 at the defined positions. When the cold plate 105 or the battery block 115 is to be serviced or otherwise replaced, the cold plate 105 can be unscrewed and thus removed from the battery block 115. The top layer of the cold plate 105 can also be joined to the bottom surface of the battery block 115 by applying an adhesive (e.g., acrylic polymer, polyurethane, and epoxy). The modular cold plates 105 can disconnect and release from the main coolant lines for service, maintenance, or replacement. The cold plate 105 to cold plate 105 (e.g., module to module) interconnects can share the same space as the main coolant lines but can be contained within individual channels and can be isolated from the main coolant lines to facilitate packaging and serviceability of the cold plates 105.

The system 100 can include at least one battery monitoring unit (BMU) 135. Each BMU 135 can couple with at least one battery module 125 or the cold plate 105 to provide system monitoring and controls to the battery module 125 and the cold plate 105. The BMU 135 can monitor each of the battery blocks 115 forming the battery module 125 and each of the battery cells 110 forming the battery blocks 115. For example, the BMU 135 can couple with outputs of the battery cells 110, outputs of the battery blocks 115, outputs of the battery modules or an output of a battery module 125 to receive information, such as but not limited to current data, voltage data, temperature data, and pressure data, among others. Thus, the BMU 135 can monitor and receive information and data from the battery pack, the battery submodule 120, the battery blocks 115, or the battery cells 110. The BMU 135 can couple with the outputs of the cold plates 105 (and the individual portions 130 of the cold plate 105) to receive information regarding temperature and pressure data, among others. The BMU 135 can generate control signals for the cold plate 105, the battery module 125, the battery blocks 115, or the battery cells 110. For example, responsive to receiving current data, voltage data, temperature data, or pressure data, the BMU 135 can generate control signals to modify a current level, voltage level, or temperature level of the respective the battery pack, the battery module 125, the battery blocks 115, or the battery cells 110 receiving the respective control signals. The BMU 135 can generate control signals to activate or deactivate (e.g., turn on, turn off) the cold plate 105, the battery pack, one or more battery submodule 120, one or more battery blocks 115, or one or more battery cells 110 receiving the respective control signals.

The BMU 135 can generate control signals for the cold plate 105 to provide cooling at a cooling level, as indicated in the control signal, for the battery module 125, one or more battery blocks 115 of the battery module 125, or one or more battery cells 110 of the battery module 125, or to provide cooling at a predetermined cooling level, as indicated in the control signal, for portions of the battery module 125, one or more battery blocks 115 of the battery module 125, or one or more battery cells 110 of the battery module 125. The BMU 135 can determine, according to the monitoring, to control the cold plate 105 coupled with the battery module 125 to control, regulate, or reduce the temperature within the battery module 125, within one or more battery blocks 115 forming the battery module 125, or for one or battery cells 110 forming the one or more battery blocks 115, for example. The BMU 135 can control the cold plate 105 or other components of the corresponding battery module 125, such as one or more battery blocks 115 or one or more battery cells 110. For example, the BMU 135 can monitor the cold plate 105, the battery module 125, one or more battery blocks 115, or one or more battery cells 110 and can generate or report a status or provide local diagnostics of the corresponding cold plate 105, submodule 120, battery module 125, battery block 105, or battery cell 110. The BMU 135 can generate an alert or notification, for example, a notification for a user of the battery pack to indicate when a particular battery cell 110, battery block 105, battery module 125, or battery pack 505 should be repaired, replaced, or serviced.

The BMU 135 can be coupled with a bottom layer of the battery module 125 or a bottom layer of the cold plate 105. For example, the cold plate 105 can include a top layer that is coupled to the bottom layer of the battery module 125 and a top layer of the BMU 135 can be coupled with the bottom layer of the cold plate 105 such that the cold plate 105 is disposed between the battery module 125 and the monitoring circuitry. The BMU 135 can include a single BMU 135 coupled with the cold plate 105 and each of the battery blocks 115 forming the battery module 125. The BMU 135 can include multiple battery monitoring units, with each cold plate 105 coupled with at least one of the battery blocks 115 of the battery module 125 and coupled with the cold plate 105 or cooling systems. The BMU 135 can include a circuit board (e.g., printed circuit board) or circuit components coupled with, disposed on, or embedded in a non-conductive material or layer. The BMU 135 of the battery module 125 can be removable from the battery module 125 or battery pack and replaceable by another monitoring circuitry. The BMU 135 can be disconnected from the battery module 125 or battery pack and replaced with another BMU 135 without impacting the operation of the battery module 125 or battery pack or modifying the arrangement of the battery cells 110, battery blocks 115, the battery submodule 120 or battery pack. The BMU 135 can be disconnected from the battery module 125 or battery pack and replaced with another BMU 135 without damaging or modifying the battery module 125 or battery pack.

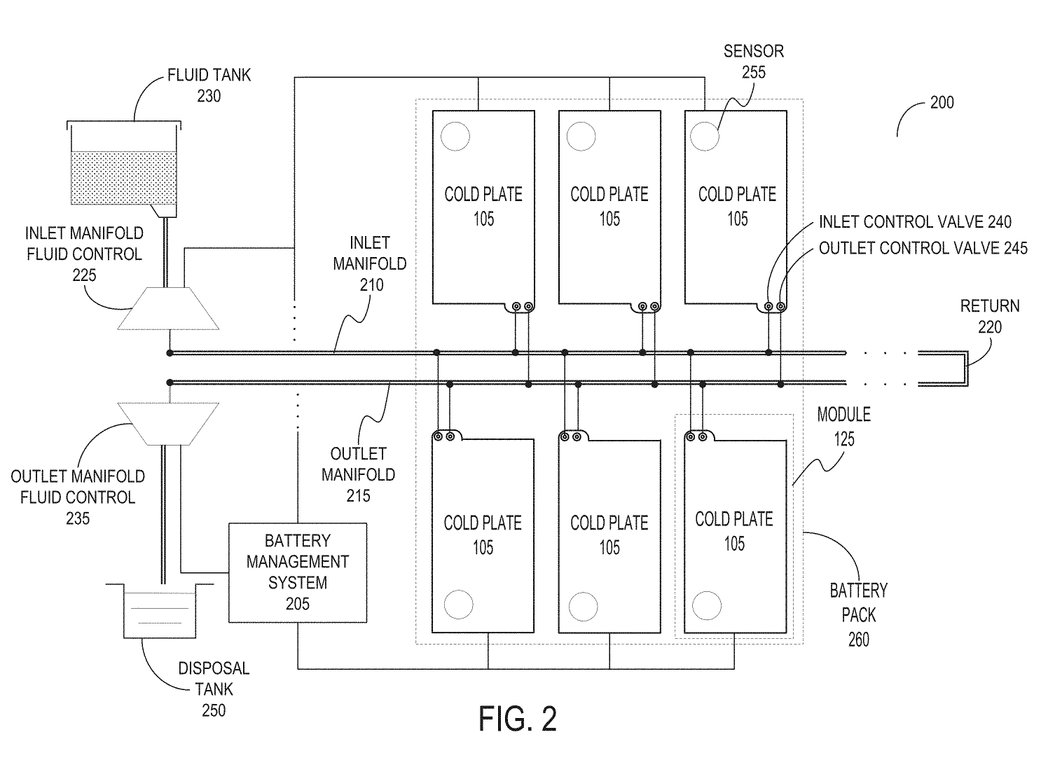

FIG. 2 depicts an example overhead view of an illustrative embodiment of a temperature control system 200 for an energy storage system. The system 200 can include the one or more of the components of the system 100. The system 200 can include a set of cold plates 105 each thermally coupled with at least one battery block 115 of the battery module 125. Each cold plate 105 can be disposed beneath at least one battery submodule 120 (as depicted). Each cold plate 105 can be thermally coupled with the at least one battery block 115 disposed above the cold plate 105. The set of cold plates 105 (e.g., six cold plates 105 as depicted) or one cold plate 105 divided into multiple portions 130 can be disposed beneath the battery module 125. The set of cold plates 105 can be thermally coupled with the battery module 125 disposed above the cold plates 105. The system 200 can also include at least one battery pack 260. The battery pack 260 can include one or more battery modules 125. As the cold plates 105 can be thermally coupled with the battery blocks 115, the submodules 120, and the battery submodule 120 forming the battery pack 260, the battery pack 260 can be thermally coupled with the set of cold plates 105.

Each cold plate 105 can define or include at least one port to receive liquid into the cold plate 105 or release liquid from the cold plate 105. The port can be an aperture or a hole exposing the receptacle within the cold plate 105 to the outside. The port of the cold plate 105 can include at least one inlet (sometimes referred herein as an ingress port) to receive coolant into the cold plate 105. The port of the cold plate 105 can include at least one outlet (sometimes referred herein as an egress port) to release liquid from the cold plate 105. Each cold plate 105 can have at least one valve to control flow of liquid into or out of the cold plate 105. The at least one valve can be connected to one of the ports, such as the inlet or the outlet. The at least one valve for the cold plate 105 can be any type of valve, such as a butterfly valve, a check valve, a ball valve, a plug valve, and a gate valve, among others. The at least one valve of the cold plate 105 each can include at least a port, a body, a restrictive member, and an actuator, among other components. The ports can be a passage to allow liquid to flow pass through the valve. One port can be for the liquid from the outside of the cold plate 105. Another port can be for the liquid to inside the cold plate 105. The body can be an encasing to contain inner components of the valve, such as the restrictive member. The body can define a passage between the ports through which the liquid can flow. The restrictive member can be within the body, and can variably allow or obstruct flow of the liquid through the body of the valve depending on the position of the restrictive member within the body of the valve. The restrictive member can be a disc, a ball, a hinge, a trunnion, a plug, a rotor, or any other structural member to variably allow or obstruct flow of liquid passing through the valve. The actuator can control a position of the restrictive member within the valve. The actuator can include a rotor, a lever, or another mechanism to control the position of the restrictive member within the valve to control flow of liquid through the valve. The actuator can be controlled remotely or electronically to set the position of the restrictive member.

The at least one valve of each cold plate 105 can include an inlet control valve 240 and an outlet control valve 245. The inlet control valve 240 of each cold plate 105 can variably control an intake rate of flow of coolant into the receptacle (or coolant channel) of the cold plate 105. The inlet valve control 240 can be coupled with an inlet manifold 210 of the system 200. From the inlet manifold 210, the inlet control valve 240 can take in or receive the coolant flowing into the receptacle of the cold plate 105. The inlet control valve 240 can partially or fully block or obstruct the flow of the coolant from the inlet manifold 210 through an inlet of the cold plate 105, by controlling a size or diameter of an aperture of the inlet or inlet control valve 240 available for coolant flow at a specific time. The inlet control valve 240 can have a temperature sensor to measure a temperature of the coolant passing through the inlet or the inlet control valve 240 entering into the cold plate 105. Additionally, the outlet control valve 245 of each cold plate 105 can variably control an outtake rate of flow of the liquid from the receptacle of the cold plate 105. The outlet control valve 245 can be coupled with an outlet manifold 215 of the system 200. The outlet control valve 245 can expel or release liquid from the receptacle of the cold plate 105 into the outlet manifold 215. The released liquid can include the coolant received via the inlet control valve 240. The outlet control valve 245 can partially or fully block or obstruct the flow of the liquid out from the receptacle of the cold plate 105. The outlet control valve 245 can control the flow of the coolant from the outlet manifold 215 through an outlet of the cold plate 105, by controlling a size or diameter of an aperture of the outlet or outlet control valve 245 available for liquid flow at a specific time. The outlet control valve 245 can have a temperature sensor to measure a temperature of the liquid passing through the outlet or the outlet control valve 245 released from the cold plate 105. The inlet control valve 240 and the outlet control valve 245 can have a maximum flow rate dependent on the structuring of the components of the valve, such as the ports, body, restrictive member, and the actuator.

The system 200 can include at least one inlet manifold 210 and at least one outlet manifold 215. The inlet manifold 210 and the outlet manifold 215 can each include a pipe in any shape, such as a hollow prism with a polygonal base or a cylindrical tube or pipeline. The inlet manifold 210 and the outlet manifold 215 can also include a main pipeline and one or more branch pipelines each connected to the inlet control valves 240 and the outlet control valves 245 of the one or more cold plates 105. The inlet manifold 210 can be coupled with at least one inlet manifold fluid control 225 to receive the coolant to provide to the cold plates 105 via the inlet control valves 240. The coupling between each inlet control valve 240 and the inlet manifold 210 can be removable (e.g., using a hose coupling). The outlet manifold 215 can be coupled with at least one outlet manifold fluid control 235 to receive the liquid released from the cold plates 105 through the outlet control valves 245. The coupling between each outlet control valve 245 and the outlet manifold 215 can be removable (e.g., using a hose coupling). In this manner, each cold plate 105 can be removably coupled to the inlet manifold 210 and the outlet manifold 215.

The inlet manifold 210 and the outlet manifold 215 can handle flow of coolant through various components of the system 200, such as the cold plates 105 thermally coupled to one or more battery submodule 120. The inlet manifold 210 and the outlet manifold 215 can form at least one fluid conveyance to handle flow of liquid through the system 200. One end of the inlet manifold 210 and one end of the outlet manifold 215 can be connected to each other to form a single fluid conveyance. The division between the inlet manifold 210 and the outlet manifold 215 can be defined at a return 220. The return 220 can correspond to any section of the fluid conveyance between couplings of all the inlet control valves 240 to the fluid conveyance, and coupling of all the outlet control valves 245 to the fluid conveyance. In some example implementations, the inlet manifold 210 and the outlet manifold 215 may not be directly connected to one another via the ends of the inlet manifold 210 and the outlet manifold 215. The inlet manifold 210 and the outlet manifold 215 can be indirectly connected to each other via the cold plates 105 (e.g., channels in the cold plates 105) to form multiple fluid conveyances without multiple branches. The fluid conveyance can be formed from the inlet manifold 210, through a branch pipeline connected to the inlet control valve 240 into the cold plate 105, through another branch pipeline connected to the outlet control valve 245 from the cold plate 105, and into the outlet manifold 215. In this manner, the cold plates 105 of the system 200 can function as the return 220 linking the inlet manifold 210 to the outlet manifold 215.

The inlet manifold 210, the outlet manifold 215, or the return 220 can be positioned, distributed, arranged, or disposed in any manner relative to the battery submodules 120, battery module 125 or the battery blocks 115 of the battery module 125. The inlet manifold 210, the outlet manifold 215, and the return 220 can be disposed or arranged coplanar relative to one another. The inlet manifold 210, the outlet manifold 215, and the return 220 can be disposed or arranged on substantially the same plane as the cold plates 105 (e.g., deviation of between 0° to 15° in inclination or declination and an offset of between 0 to 10 cm). At least a portion of the inlet manifold 210 and the outlet manifold 215 can be positioned, arranged, or disposed above or beneath at least one battery module 125. The portion of the inlet manifold 210 and the outlet manifold 215 can be disposed around the battery module 125 (e.g., along an outer perimeter of the battery module 125). The portion of the inlet manifold 210 and the outlet manifold 215 can be disposed along a midsection of the battery pack 260 (e.g., as depicted), between a cluster or arrangement of battery submodules 120 for instance. The portion of the inlet manifold 210 and the outlet manifold 215 can be disposed along an outer perimeter of the bottom surface of the battery module 125. The portion of the inlet manifold 210 and the outlet manifold 215 can be arranged or disposed between the battery blocks 115, or the battery submodules 120 of the battery pack 260. The return 220 can be positioned, arranged, or disposed integrally within the battery module 125. The return 220 can be disposed above or beneath the battery module 125. The return 220 can be disposed around the battery module 125 (e.g., along an outer perimeter of the battery module 125). The return 220 can be disposed outside the outer perimeter of the battery pack 260 (e.g., as depicted).

The system 200 can include at least one inlet manifold fluid control 225. The inlet manifold fluid control 225 can be coupled with the inlet manifold 210 to control circulation of the coolant in the inlet manifold 210. The inlet manifold fluid control 225 can include or can be coupled with at least one fluid tank 230 via a fluid conveyance (e.g., a pipe, channel). The fluid tank 230 can contain, hold, store, or otherwise have the coolant. The coolant contained in the fluid tank 230 can be a liquid or gas. Examples of coolants can include water, antifreeze, polyalkylene glycol, liquid nitrogen, hydrofluorocarbons (HFCs), and perfluorocarbons (PFCs), among others. The inlet manifold fluid control 225 can control flow of coolant from the fluid tank 230 into the inlet manifold 210. The inlet manifold fluid control 225 can include a pressure regulator to control circulation of the coolant into the inlet manifold 210. The pressure regulator for the inlet manifold fluid control 225 can be a single-stage regulator or a double-stage regulator. The pressure regulator of the inlet manifold fluid control 225 can include at least one of a loading element, a restricting element, and a measuring element. The loading element can apply a pressure to the coolant introduced into the inlet manifold 210. The loading element can include a diaphragm actuator and a spring to apply force to exert pressure to the coolant. The restricting element can include a valve to variably control flow of the coolant out of the fluid tank 230 and into the inlet manifold 210. The measuring element can measure or determine a rate of flow of the coolant from the fluid tank 230, through the inlet manifold fluid control 225, and into the inlet manifold 210. The inlet manifold fluid control 225 can be integrated with the battery module 125, the battery pack 260, or the one or more battery blocks 115 of the battery module 125. The inlet manifold fluid control 225 can be physically remote from the battery blocks 115 and the battery module 125.

The system 200 can include at least one outlet manifold fluid control 235. The outlet manifold fluid control 235 can be coupled with at least the outlet manifold 215. The outlet manifold fluid control 235 can control flow of liquid out from the outlet manifold 215. The outlet manifold fluid control 235 can include a pressure regulator to control circulation of liquid from the outlet manifold 215. The pressure regulator for the outlet manifold fluid control 235 can be a single-stage regulator or a double-stage regulator. The pressure regulator of the outlet manifold fluid control 235 can include at least one of a loading element, a restricting element, and a measuring element. The loading element can apply a pressure to the liquid drawn up from the outlet manifold 215. The loading element can include diaphragm actuator and a spring to apply the force to exert the pressure to the liquid. The restricting element can include a valve to variably control flow of the liquid out from the outlet manifold 215. The measuring element can measure or determine a rate of flow of the liquid from the outlet manifold 215 to the outlet manifold fluid control 235. The outlet manifold fluid control 235 can include or can be coupled with a disposal tank 250. The outlet manifold fluid control 235 can transfer the liquid released from the outlet manifold 215 into the disposal tank 250. The disposal tank 250 can be a container for holding any liquid released by the cold plates 105 via the outlet control valve 245 and the outlet manifold 215. The outlet manifold fluid control 235 can be coupled with the fluid tank 230. The outlet manifold fluid control 235 can transfer the liquid released from the outlet manifold 215 into the fluid tank 230. The outlet manifold fluid control 235 can select between the disposal tank 250 and the fluid tank 230 to transfer the liquid release from the outlet manifold 215. The outlet manifold fluid control 235 can be integrated with the battery module 125, the battery pack 260 or the one or more battery blocks 115 of the battery module 125. The outlet manifold fluid control 235 can be physically remote from the battery blocks 115 and the battery module 125.

The system 200 can include at least one battery management system (BMS) 205 to control various components of the system 200. The BMS 205 can include at least one processor, at least one memory, at least one input/output (I/O) interface, and at least communication interface. The processors of the BMS 205 can be, for example, a field-programmable gate array (FPGA), a system on a chip (SOC), a microcontroller, or an application-specific integrated circuit (ASIC), or other logical circuitry, to carry out the functionalities detailed herein. The BMS 205 can include one or more components of a computing system 600 as detailed herein below. To control the components of the system 200, the BMS 205 can be communicatively coupled with the one or more cold plates 105, the one or more battery blocks 115, the one or more battery submodule 120, the battery module 125, one or more of the BMUs 135, the at least one inlet manifold fluid control 225, the at least one outlet manifold fluid control 235, the inlet control valves 240, the outlet control valves 245, and one or more sensors 255, among others. The communicative coupling can be via a wired connection or wirelessly (e.g., using near-field communications protocols and techniques). Via the communicative coupling, the BMS 205 can manage and control operations of individual BMUs 135 and components of the one or more battery blocks 115, the one or more submodules 120, and one or more battery modules 125 of the battery pack 260.

The one or more components of the BMS 205 can be positioned, distributed, arranged, or disposed in any manner relative to the battery module 125 or to the one or more battery blocks 115, battery submodules 120 of the battery module 125, the BMUs 135, or the battery pack 260. The BMS 205 can be integrated one or more of the battery blocks 115. For example, the processors and memory of the BMS 205 can be distributed along a top surface or within a body of the battery block 115 between individual battery cells 110. The BMS 205 can be integrated into the battery module 125. For example, the processors and memory of the BMS 205 can be distributed along a top surface or with a body of the battery module 125 between the battery blocks 115 as well as a top surface of the battery blocks 115. The BMS 205 can be physically remote from the one or more battery blocks 115 or the battery module 125 (e.g., as depicted). For example, the battery module 125 along with the battery blocks 115 can be located in a bottom of the electrical vehicle along a chassis. In contrast, the BMS 205 can be situated in a hood of the vehicle separated from the battery module 125 or the battery blocks 115. A subset of the components of the BMS 205 can be physically remote from the one or more battery blocks 115 or the battery module 125, while another subset of the components of the BMS 205 can be integrated into the battery block 115 or the battery module 125. The BMS 205 can also be part of or be integrated with one or more BMUs 135. The one or more components of the BMS 205 can housed, contained, arranged, or disposed in the BMUs 135 disposed relative to one of the battery blocks 115, the submodules 120, and the battery modules 125. The functionalities of the individual BMUs 135 described above can be incorporated into the BMS 205. Conversely, the functionalities of the BMS 205 can be incorporated into the individual BMUs 135.

The system 200 can include one or more sensors 255. The one or more sensors 255 can be positioned, distributed, arranged, or disposed in any manner relative to the battery module 125, the one or more battery blocks 115 of the battery module 125, the individual battery cells 110 of the battery block 115, or the BMS 205. The sensors 255 can be arranged or disposed on the BMU 135 for each battery block 115, submodule 120, or battery module 125. The sensors 255 can be arranged or disposed in the BMS 205 itself. For example, using the case of battery blocks 115 for illustration, each battery block 115 can be equipped or can include one or more sensors 255. The one or more sensors 255 can be integrated into each battery block 115. For example, the sensors 255 can be integrated within a body of the battery block 115 between individual battery cells 110. The one or more sensors 255 can be distributed, arranged, or disposed along one or more surfaces of each battery block 115, such as the top surface, sidewalls, and the bottom surface of the battery block 115. For example, one sensor 255 can be placed on a bottom surface of the battery block 115, while another sensor 255 can be placed on a top surface of the battery block 115. The battery module 125 can be equipped or can include one or more sensors 255. The one or more sensors 255 can be integrated into battery module 125. The one or more sensors 255 can be distributed, arranged, or disposed along one or more surfaces of battery module 125, such as the top surface, sidewalls, and the bottom surface of battery module 125. The one or more sensors 255 can be integrated into at least one battery cell 110 of one or more battery blocks 115. The one or more sensors 255 can be distributed, arranged, or disposed along one or more surfaces of battery cell 110, such as the top surface, sidewalls, and the bottom surface. The one or more sensors 255 can be part of the BMS 205 itself. The BMS 205 can be integrated into the battery block 115, the battery module 125, or the battery pack 260 as described above.

Each sensor 255 can measure one or more characteristics of the battery block 115, submodule 120, or battery module 125 that the sensor 255 is disposed on. For example, using the case of battery blocks 115 for illustration, one or more characteristics of each battery block 115 can include a temperature from heat radiated by the battery block 115, a detection of gas released from the battery block 115, and a pressure exerted by the battery block 115. The sensor 255 can include at least one thermometer to measure a temperature of heat originating from the battery block 115. The thermometer can be an infrared thermometer, a liquid crystal thermometer, a vapor pressure thermometer, a thermistor, a column block thermometer, and a thermocouple, a quartz thermometer, among others. The sensor 255 can include at least one gas detector to identify one or more gaseous substances released from the battery block 115 or from the individual battery cells 110 in the battery block 115. The gas detector can also determine a concentration (measured in parts-per notation) of the one or more gaseous substances released from the battery block 115. The gaseous substances identified by the gas detector can include hydrocarbons, ammonia, carbides (e.g., carbon monoxide and carbon dioxide), cyanide, halide, sulfides (e.g., hydrogen sulfide, sulfur dioxide, sulfur trioxide, and disulfur monoxide), nitrides, fluorides (e.g., hydrogen fluoride and phosphoryl fluoride), volatile organic compounds (e.g., formaldehyde and benzene), and phosphites among others. The gas detector of the sensor 255 can include an electrochemical gas sensor, a flame ionization detector, an infrared point sensor, a pellistor (e.g., catalytic bead sensor), thermal conductivity meter, and an ultrasonic gas leak detector, among others. The sensor 255 can include at least one force meter or a pressure gauge to measure a pressure exerted from within the battery cell 110 or the battery block 115. The force meter can be a dynamometer, a newton meter, and a spring scale, among others to measure force exerted against an outer surface of the battery cell 110 or the battery block 115. The pressure gauge can include a hydrostatic pressure gauge (e.g., a piston gauge, a liquid column, and a McLeod gauge), a mechanical gauge (e.g., a bellow, a Bourdon gauge, and a diaphragm), an electronic pressure sensor (e.g., a capacitive sensor, an electromagnetic gauge, a piezoresistive strain gauge, and an optical sensor), and a thermal conductivity gauge (e.g., Pirani gauge), among others.

With the one or more characteristics of the battery block 115, submodule 120, or battery module 125 measured, each sensor 255 can generate at least one signal to relay, transmit, or otherwise provide to the BMS 205. The signal can be indicative of the measure characteristic of the battery block 115, submodule 120, or battery module 125. The signal can include the temperature measurement of heat from the battery block 115, submodule 120, or battery module 125, the presence of gases released from the battery block 115, submodule 120, or battery module 125, or the measured pressure exerted from within the battery block 115, submodule 120, or battery module 125. The sensor 255 can constantly send the signal with the measured characteristics of the battery block 115, submodule 120, or battery module 125. The sensor can also send the signal with the measured characteristics of the battery block 115, submodule 120, or battery module 125 at a periodic interval (e.g., every 5 seconds to 8 minutes). The signal can also include an identifier for the battery block 115, submodule 120, or battery module 125 to associate the measurements of the one or more characteristics with the battery block 115, submodule 120, or battery module 125. The same set of sensors 255 can be shared or be common between multiple battery blocks 115 or battery submodule 120. In such cases, the signal generated by the sensor 255 can be for the multiple battery blocks 115 or battery submodule 120 to which the sensor 255 is disposed on.

For each battery block 115, submodule 120, or battery module 125, the BMS 205 can receive the signal indicative of the one or more characteristics of the battery block 115, submodule 120, or battery module 125. The BMS 205 can receive the signal from the one or more sensors 255 disposed on or otherwise associated with the battery block 115, submodule 120, or battery module 125. The BMS 205 can also retrieve the measurements of the one or more characteristics from the sensors 255 disposed on or otherwise associated with the battery block 115, submodule 120, or battery module 125. From the set of battery blocks 115 or battery submodule 120 in the battery module 125, the BMS 205 can identify the battery block 115, submodule 120, or battery module 125 associated with the signal or the measurement from the sensor 255. The BMS 205 can parse the received signal to identify the one or more measured characteristics of the battery block 115, submodule 120, or battery module 125 and the identifier for the battery block 115, submodule 120, or battery module 125. Based on the identifier, the BMS 205 can identify the battery block 115, submodule 120, or battery module 125 associated with the measurements. The BMS 205 can also identify the battery block 115, submodule 120, or battery module 125 based on a pin number through which the signal is received. From the measurements, the BMS 205 can identify the temperature of the heat from the battery block 115, submodule 120, or battery module 125 measured by the thermometer of the sensor 255. In addition, the BMS 205 can identify the one or more gaseous substances released by the battery block 115, submodule 120, or battery module 125 identified by the gas detector of the sensor 255. The BMS 205 can identify the pressure exerted from within the battery block 115, submodule 120, or battery module 125 measured by the force meter or the pressure gauge of the sensor 255.

For each cold plate 105, the BMS 205 (or individual BMU 135 connected to the cold plate 105) can set, calculate, or otherwise determine a target flow rate for the coolant through the inlet or the outlet of the cold plate 105 based on the one or more characteristics measured for the battery block 115, the submodule 120, or the battery module 125 thermally coupled with the cold plate 105. In determining the target flow rate, the BMS 205 can determine a target intake flow rate of the coolant to be provided to the cold plate 105 via the inlet control valve 240 based on the one or more measured characteristics. The BMS 205 can also determine a target outtake flow rate of the liquid to be released from the cold plate 105 via the outlet control valve 245 based on the one or more measured characteristics. The BMS 205 can initially set the target flow rates of the cold plates 105 to a default flow rate, including a default intake flow rate for the inlet control valve 240 and a default outtake flow rate for the outlet control valve 245. The default intake flow rate for the inlet control valve 240 and the default outtake flow rate for the outlet control valve 245 can vary from cold plate 105 to cold plate 105 to account for a distance between the inlet manifold fluid control 225 and an inlet of the cold plate 105 thermally coupled with the battery block 115, submodule 120, or battery module 125 and a distance between the outlet manifold fluid control 235 an outlet of the cold plate 105. The default intake flow rate can range between 0 and 35 L/min and the default outtake flow rate can range between 0 and 35 L/min.

To determine target intake flow rate and the target outtake flow rate, the BMS 205 (or individual BMU 135 connected to the cold plate 105) can compare the one or more characteristics for the battery block 115, submodule 120, or battery module 125 with a flow rate specification. The flow rate specification can define a mapping of the intake flow rate and the outtake flow rate with the measured temperature, detected gaseous substances, and the pressure for the battery block 115, submodule 120, or battery module 125. For example, the flow rate specification can indicate an intake flow rate of 40 L/min and an outtake flow rate of 40 L/min for a measured temperature between 15° C. to 35° C., with sulfides between 20 to 30 ppm, and pressure between 800 to 1,000 kPa. The flow rate specifications can differ in the intake flow rate and the outtake flow rate among the battery blocks 115, submodule 120, or battery module 125 to account for a distance between the inlet manifold fluid control 225 and an inlet of the cold plate 105 thermally coupled with the battery block 115, submodule 120, or battery module 125 and a distance between the outlet manifold fluid control 235 an outlet of the cold plate 105.

In addition, the BMS 205 (or individual BMU 135 connected to the cold plate 105) can determine the target flow rate of the coolant for the cold plate 105 based on a deviation measure from normal operations for the battery block 115, submodule 120, or battery module 125 thermally coupled with the cold plate 105. The normal operations can specify a range of characteristics to maintain a level of performance for the battery cells 110 of the battery block 115, submodule 120, or battery module 125. For example, the normal operations can specify a temperature range of 0° C. to 45° C., no presence of gaseous substances beside atmospheric gases (e.g., oxygen, carbon dioxide, and nitrogen), and an exerted pressure between 0 to 200 kPa. In determining the deviation measure, the BMS 205 can calculate a difference between the measured temperature and the temperature range specified for normal operations. The BMS 205 can also determine a difference between the detected gaseous substances and the gaseous substances specified for normal operations. The BMS 205 can further calculate a difference between the measured pressure and the pressure range designated for normal operations, sometimes referred as a deviation measure. Based on a combination of the differences (e.g., a weighted average), the BMS 205 can determine the deviation measure. Using the deviation measure for the battery block 115, submodule 120 or battery module 125, the BMS 205 can determine the target intake flow rate for the inlet control valve 240 and the outtake flow rate for the outlet control valve 245 of the cold plate 105 thermally coupled with the battery block 115, submodule 120, or battery module 125. For higher deviation measures, the BMS 205 can set a higher target intake flow rate and a lower target outtake flow rate. For lower deviation measures, the BMS 205 can set a lower target intake flow rate and a higher target outtake flow rate. For zero deviation measures, the BMS 205 can set the target intake flow rate and the target outtake flow rate to the default.

The BMS 205 (or individual BMU 135 connected to the cold plate 105) can also determine the target flow rate of the coolant for the cold plate 105 based on a risk metric of a failure event for the battery block 115 or submodule 120. The failure event can include a combustion (e.g., presence of combustible gases) and a thermal runaway (e.g., a temperature of more than 110° C. or a pressure of more than 1,000 kPa), among others. The risk metric can indicate a likelihood of an occurrence of the failure event within a time period (e.g., less than 30 seconds). Based on the measured characteristics for the battery block 115 or submodule 120, the BMS 205 can calculate, estimate, or determine the risk metric of the failure event. The BMS 205 can determine the risk metric for the failure event by inputting the measured characteristics into a function for the failure event. The function can correlate the measure characteristics, such as temperature, pressure, and presence of certain gaseous substances to the likelihood of an occurrence of the failure event. Using the risk metric, the BMS 205 can set or determine the target flow rate for the coolant to the cold plate 105. For higher risk metrics, the BMS 205 can set a higher target intake flow rate and a lower target outtake flow rate. For lower risk metrics, the BMS 205 can set a lower target intake flow rate and a higher target outtake flow rate. For zero risk metrics, the BMS 205 can set the target intake flow rate and the target outtake flow rate to the default.

The BMS 205 (or individual BMU 135 connected to the cold plate 105) can determine the target flow rate of the coolant for the cold plate 105 based on a detection of an occurrence of the failure event for the battery block 115 or the submodule 120. As described above, the failure event can include a combustion event (e.g., presence of combustible gases) and a thermal runaway event (e.g., a temperature of more than 110° C. or a pressure of more than 1,000 kPa), among others. The occurrence of the failure event can result in at least a partial deformation of the cold plates 105. For example, a part of the top layer of the cold plates 105 flush against a portion of the bottom surface of the submodule 120 to which heat from a thermal runaway event transfers to can be deformed due to the heat. Melting of (e.g., portions of) the top layer can cause a drop in pressure in the coolant contained in the cold plate 105 because of the deformation, thus triggering more coolant intake to cool the submodule 120 disposed above the cold plate 105. The BMS 205 can detect the occurrence of the failure event from the characteristics measured for the battery block 115 or submodule 120, such as temperature, pressure (e.g., of coolant, gas), and presence of certain gaseous substances. The BMS 205 can compare the measured characteristics to a range of values corresponding to a failure event. For example, the range of values for a failure event can include at least one of: a temperature of more than 110° C., a pressure of more than 1,000 kPa, and presence of sulfides, among others. The BMS 205 can determine that the measured characteristics match the range of values corresponding to a failure event. Responsive to the determination, the BMS 205 can set the target intake flow rate to a defined value (e.g., to a maximum flow value) for the inlet control valve 240 of the cold plate 105. The BMS 205 can set the target outtake flow rate to zero for instance, for the outlet control valve 245 of the cold plate 105 to hold or maintain as much coolant as possible within a locality of the cold plate 105 (e.g., such that the coolant is released from the cold plate 105 onto portions of the battery module 125) to alleviate the failure event, and to prevent the coolant pressure within the cold plate from falling further (e.g., due to the coolant being released onto the portions of the battery module 125) for instance.

The BMS 205 (or individual BMU 135 connected to the cold plate 105) can determine the target flow rate of the coolant for the cold plate 105 based on the temperatures measured on the inlet control valve 240 or the outlet control valve 245. The BMS 205 can compare the temperature measured by the temperature sensor of the inlet control valve 240 to the temperature measured by the temperature sensor of the outlet control valve 245 and a temperature differential margin (sometimes referred as temperature difference margin). The temperature differential margin can be set to account for an expected increase in temperature of the coolant as the coolant passes through the cold plate 105 from the inlet to the outlet under normal operations of the submodule 120 thermally coupled to the cold plate 105. The temperature differential margin can be, for example, between 2° C. to 40° C. The BMS 205 can determine that the temperature measured on the inlet control valve 240 is less than a sum of the temperature measured on the outlet control valve 245 and the temperature differential margin. This may indicate that the submodule 120, the battery module 125, or the battery block 115 thermally coupled to the cold plate 105 is operating properly. Based on the determination, the BMS 205 can maintain the current intake flow rate as the target intake flow rate and the current outtake flow rate as the target outtake flow rate. The BMS 205 can determine that the temperature measured on the inlet control valve 240 is greater than a sum of the temperature measured on the outlet control valve 245 and the temperature differential margin. This may indicate that the submodule 120, the battery module 125, or the battery block 115 thermally coupled to the cold plate 105 may radiating more heat than in normal operations. Based on the determination, the BMS 205 can increase the intake flow rate via the inlet control valve 240 and can decrease the outtake flow rate via the outlet control valve 245. In this manner, the BMS 205 can coordinate operations of the inlet control valve 240 and the outlet control valve 245, and can synchronize the determination of the target intake flow rate and the target outtake flow rate.

The BMS 205 (or individual BMU 135 connected to the cold plate 105) can send a signal to individually control the at least one valve of each cold plate 105 based on the target flow rate for the cold plate 105. The signal can specify the target flow rate for the at least one valve of the cold plate 105. The signal can include an open command to open the at least one valve of the cold plate 105. The open command to the inlet or the inlet control valve 240 can specify an increase in the size or diameter of the aperture of the inlet or the inlet control valve 240 to achieve the target intake flow rate. The open command to the inlet or the outlet control valve 245 can specify an increase in the size or diameter of the aperture of the outlet or the outlet control valve 245 to achieve the target outtake flow rate. The signal can include a close command to close the at least one valve of the cold plate 105. The close command to the inlet or the inlet control valve 240 can specify a decrease in the size or diameter of the aperture of the inlet or the inlet control valve 240 to achieve the target intake flow rate. The open command to the inlet or the outlet control valve 245 can specify a decrease in the size or diameter of the aperture of the outlet or the outlet control valve 245 to achieve the target intake flow rate. The signal can include a maintain command to maintain the flow rate at least one valve of the cold plate 105. The maintain command to the inlet control valve 240 can specify maintenance of the size or diameter of the aperture of the inlet or the inlet control valve 240 at the current size or diameter to keep constant at the target intake flow rate. The maintain command to the inlet control valve 240 can specify maintenance of the size or diameter of the aperture of the inlet or the inlet control valve 240 at the current size or diameter to keep constant at the target outtake flow rate. The signal can include a throttle command to repeatedly open and close the at least one valve at a specified rate. Using the target flow rate, the BMS 205 can calculate the specified rate to achieve the target flow rate through the at least one valve of the cold plate 105. The throttle command to the inlet control valve 240 can specify opening and closing of the aperture of the inlet or the inlet control valve 240 at the specified rate. The throttle command to the outlet control valve 245 can specify opening and closing of the aperture of the outlet or the outlet control valve 245 at the specified rate.

With receipt of the control signal from the BMS 205, the at least one valve of the cold plate 105 can set the flow rate in accordance to the signal. The actuator in the valve (e.g., the inlet control valve 240 and the outlet control valve 245) can control the position of the restrictive member within the body to achieve the specified flow rate. The actuator can also translate or map the flow rate specified in the signal from the BMS 205 to a movement of the position of the restrictive member within the body of the valve. In response to receipt of the command to open, the inlet control valve 240 can increase the size or diameter of the aperture to the specified size or diameter of the control signal via the actuator. Responsive to receipt of the command to open, the outlet control valve 245 can increase the size or diameter of the aperture to the specified size or diameter of the control signal via the actuator. In response to receipt of the command to close, the inlet control valve 240 can decrease the size or diameter of the aperture to the specified size or diameter of the control signal via the actuator. Responsive to receipt of the command to close, the outlet control valve 245 can decrease the size or diameter of the aperture to the specified size or diameter of the control signal via the actuator. In response to receipt of the command to maintain, the inlet control valve 240 can maintain the current size or diameter of the aperture. Responsive to receipt of the command to maintain, the outlet control valve 245 can maintain the current size or diameter of the aperture. In response to receipt of the command to throttle, the inlet control valve 240 can repeatedly open and close the aperture at the specified rate via the actuator. Responsive to receipt of the command to throttle, the inlet control valve 240 can repeatedly open and close the aperture at the specified rate via the actuator.

For each cold plate 105, the BMS 205 (or individual BMU 135 connected to the cold plate 105) can generate the signal to control the inlet control valve 240 of the cold plate 105 based on the target intake flow rate. The BMS 205 can identify a current intake flow rate of the inlet control valve 240 for each cold plate 105. The BMS 205 can determine a difference between the current intake flow rate and the target intake flow rate for the inlet control valve 240 of the cold plate 105. The difference can correspond to an amount that the flow rate is to be adjusted at the inlet control valve 240. Based on the difference, the BMS 205 can select one of the commands to include into the signal to control the inlet control valve 240. The BMS 205 can determine that the difference between the current intake flow rate and the target intake flow is zero. Responsive to the determination, the BMS 205 can select the maintain command for the signal for the inlet control valve 240 to maintain the intake flow rate of the coolant to the cold plate 105. The BMS 205 can determine that the target intake flow rate for the inlet control valve 240 is zero. Responsive to the determination, the BMS 205 can select the close command for the signal for the inlet control valve 240 to reduce (e.g., minimize or terminate) the flow of coolant into the cold plate 105. Responsive to the determination, the BMS 205 can send a throttle command (e.g., an updated throttle command) as a signal to the inlet control valve 240 to reduce the flow of coolant into the cold plate 105. The BMS 205 can determine that the target intake flow is greater than or equal to a maximum flow rate for the inlet control valve 240. Responsive to the determination, the BMS 205 can select the open command for the signal for the inlet control valve 240 to increase (e.g., maximize) flow of the coolant into the cold plate 105. Responsive to the determination, the BMS 205 can send a throttle command (e.g., an updated throttle command) as the signal to the inlet control valve 240 to increase flow of the coolant into the cold plate 105. The BMS 205 can determine that the difference between the current intake flow rate and the target intake flow rate is non-zero. Based on the determination, the BMS 205 can select the adjustment command for the signal for the inlet control valve 240 to adjust the flow rate of the coolant into the cold plate 105 to the target intake flow rate.

Additionally, the BMS 205 (or individual BMU 135 connected to the cold plate 105) can also generate the signal to control the outlet control valve 245 of the cold plate 105 based on the target outtake flow rate. The BMS 205 can identify a current outtake flow rate of the outlet control valve 245 for each cold plate 105. The BMS 205 can determine a difference between the current outtake flow rate and the target outtake flow rate for the outlet control valve 245 of the cold plate 105. The difference can correspond to an amount that the flow rate is to be adjusted at the outlet control valve 245. The BMS 205 can include the difference in flow rate in the control signal for the outlet control valve 245. Based on the difference, the BMS 205 can select one of the commands to include into the signal to control the outlet control valve 245. The BMS 205 can determine that the difference between the current outtake flow rate and the target outtake flow is zero. Responsive to the determination, the BMS 205 can select the maintain command for the signal for the outlet control valve 245 to maintain the outtake flow rate of the liquid released from the cold plate 105. The BMS 205 can determine that the target outtake flow rate for the outlet control valve 245 is zero. Responsive to the determination, the BMS 205 can select the close command for the signal for the outlet control valve 245 to decrease (e.g., terminate or minimize) the flow of liquid out of the cold plate 105. The BMS 205 can determine that the target outtake flow is greater than or equal to a maximum flow rate for the outlet control valve 245. Responsive to the determination, the BMS 205 can select the open command for the signal for the outlet control valve 245 to increase (e.g., maximize) flow of the coolant into the cold plate 105. The BMS 205 can determine that the difference between the current outtake flow rate and the target outtake flow is non-zero. Based on the determination, the BMS 205 can select the adjustment command for the signal for the outlet control valve 245 to adjust the flow rate of the liquid released from the cold plate 105 to the target outtake flow rate.

In conjunction, the BMS 205 (or individual BMU 135 connected to the cold plate 105) can send a signal to the inlet manifold fluid control 225. The signal can include a command to increase the release flow rate of the coolant from the fluid tank 230 into the inlet manifold 210 via the inlet manifold fluid control 225. The signal can include a command to decrease the release flow rate of the coolant from the fluid tank 230 into the inlet manifold 210 via the inlet manifold fluid control 225. The signal can include a command to maintain the release flow rate of the coolant through the inlet manifold 210. To select one the commands, the BMS 205 can calculate or determine a total current intake flow rate of the inlet manifold 210 based on a sum of the current intake flow rate of each inlet control valve 240 of the cold plates 105. The BMS 205 can calculate or determine a total target intake flow rate of the inlet manifold 210 based on a sum of intake flow rate of each inlet control valve 240 of the cold plates 105 determined using the one or more characteristics of the battery block 115. The BMS 205 can determine a difference between the total current intake flow rate and the total target intake flow rate. The BMS 205 can determine that the total current intake flow rate is less than the total target intake flow rate. Responsive to the determination, the BMS 205 can select the command to increase the release flow rate of the coolant from the fluid tank 230 into the inlet manifold 210 to achieve the total target intake flow rate. The BMS 205 can determine that the total current intake flow rate is greater than the total target intake flow rate. Responsive to the determination, the BMS 205 can select the command to decrease the release flow rate of the coolant from the fluid tank 230 into the inlet manifold 210 to achieve the total target intake flow rate. The BMS 205 can determine that the difference is zero. Responsive to the determination, the BMS 205 can select the command to maintain the flow rate of the coolant from the fluid tank 230 into the inlet manifold 210. With receipt of the signal from the BMS 205, the inlet manifold fluid control 225 can actuate the loading element or the restricting element in the pressure regulator to achieve the flow rate of the coolant into the inlet manifold 210 specified by the signal.

The BMS 205 can send a signal to the outlet manifold fluid control 235. The signal can include a command to increase or raise the release flow rate of the liquid released from the outlet manifold 215. The signal can include a command to decrease or reduce the release flow rate of the liquid from the outlet manifold 215. The signal can include a command to maintain the release flow rate of the liquid flowing through the outlet manifold 215. To select one the commands, the BMS 205 can calculate or determine a total current outtake flow rate of the outlet manifold 215 based on a sum of the current outtake flow rate of each inlet control valve 240 of the cold plates 105. The BMS 205 can calculate or determine a total target outtake flow rate of the outlet manifold 215 based on a sum of outtake flow rate of each inlet control valve 240 of the cold plates 105 determined using the one or more characteristics of the battery module 125 or battery block 115. The BMS 205 can determine a difference between the total current outtake flow rate and the total target outtake flow rate. The BMS 205 can determine that the total current outtake flow rate is less than the total target outtake flow rate. Responsive to the determination, the BMS 205 can select the command to increase the release flow rate of the liquid from the outlet manifold 215 to achieve the total target outtake flow rate. The BMS 205 can determine that the total current outtake flow rate is greater than the total target outtake flow rate. Responsive to the determination, the BMS 205 can select the command to decrease the release flow rate of the liquid from the outlet manifold 215 to achieve the total target outtake flow rate. The BMS 205 can determine that the difference is zero. Responsive to the determination, the BMS 205 can select the command to maintain the flow rate of the liquid through the outlet manifold 215. With receipt of the signal from the BMS 205, the outlet manifold fluid control 235 can actuate the loading element or the restricting element in the pressure regulator to achieve the flow rate of the liquid from the outlet manifold 215 specified by the signal.

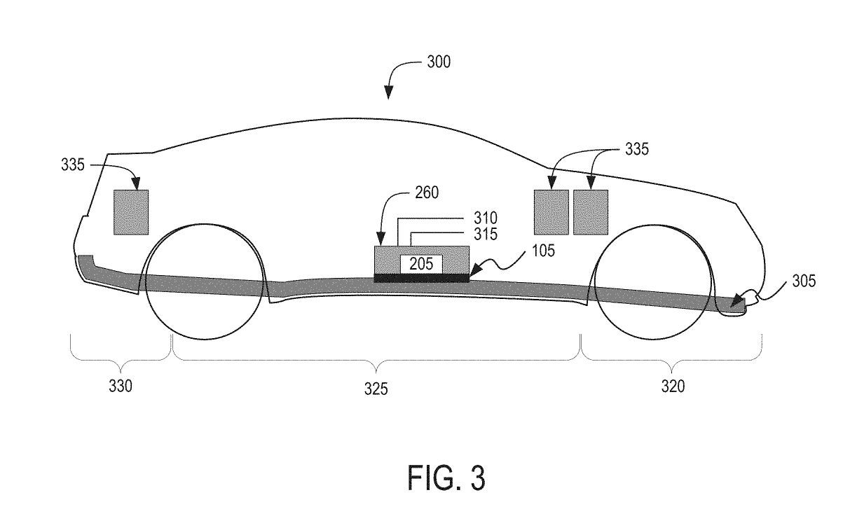

FIG. 3 depicts a cross-section view of an electric vehicle 300 installed with the battery pack 260. The electric vehicle 300 can include a chassis 305 (sometimes referred to as a frame, internal frame, or support structure). The chassis 305 can support various components of the electric vehicle 300. The chassis 305 can span a front portion 320 (e.g., a hood or bonnet portion), a body portion 325, and a rear portion 330 (e.g., a trunk portion) of the electric vehicle 300. The one or more submodule 120 and the cold plates 105, and can be installed or placed within the electric vehicle 300. The one or more battery packs 260, the cold plates 105, and the BMS 205 can be installed on the chassis 305 of the electric vehicle 300 within the front portion 320, the body portion 325 (as depicted in FIG. 3), or the rear portion 330. The BMS 205 can be integrated into the battery module 125. The battery module 125 can provide electrical power to one or more other components 335 by electrically coupling with at least one positive current collector 310 (e.g., a positive busbar) and at least one negative current collector 315 (e.g., a negative busbar). The positive current collector 310 can be electrically coupled with the positive terminal 150 of the battery module 125. The negative current collector 315 can be electrically coupled with the negative terminal 155 of the battery module 125. The one or more components 335 can include an electric engine, an entertainment system (e.g., a radio, display screen, and sound system), on-board diagnostics system, and electric control units (ECUs) (e.g., an engine control module, a transmission control module, a brake control module, and a body control module), among others.

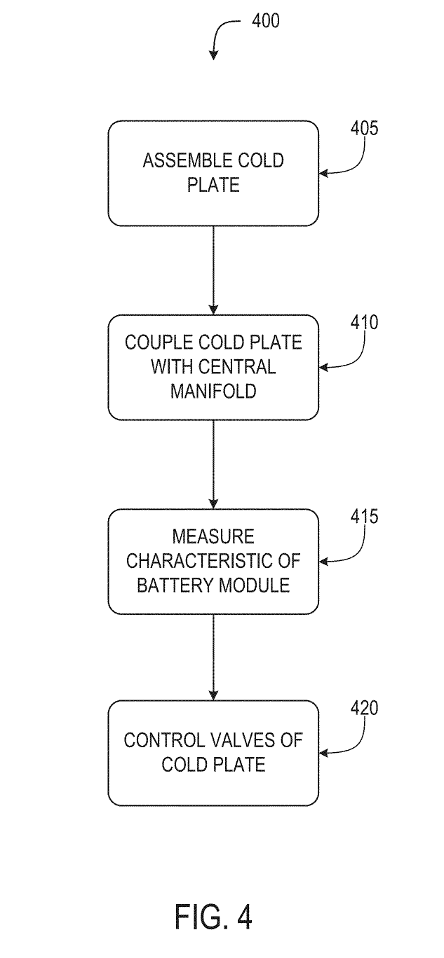

FIG. 4 depicts a flow diagram of a method 400 of controlling temperature in energy storage units. The method 400 can be performed or implemented using the components detailed above in conjunction with FIGS. 1-3 and 6. The method 400 can include assembling the cold plate 105 (ACT 405). The cold plate 105 can include a top layer and a bottom layer. The top layer can be attached to the bottom layer to form an encasing therein. The top layer can cover the receptacle for holding coolant defined along a top surface of the bottom layer. The cold plate 105 can be thermally coupled with the battery module 125 of the battery module 125. The battery module 125 can include a set of battery cells 110. The top layer can be positioned, arranged, or otherwise disposed beneath the bottom surface of the battery module 125 of the battery module 125.

The top layer of the cold plate 105 can be thermally coupled to a battery block 115 or a submodule 120 of the battery module 125, and in turn a battery pack 260 formed by one or more battery modules 125. The cold plates 105 can be arranged along the same plane as one another (e.g., co-planar relative to one another).

The method 400 can include coupling the cold plate 105 with a central manifold (ACT 410). The central manifold can include the inlet manifold 210 and the outlet manifold 215. The inlet manifold 210 can convey coolant to the cold plates 105. The outlet manifold 215 can convey fluid released from the cold plates 105. The cold plate 105 can include at least one valve, such an inlet and an outlet. The inlet can be connected to the inlet control valve 240. The inlet control valve 240 can control a rate of flow of the coolant from the inlet manifold 210 into the cold plate 105. The inlet control valve 240 can be connected to the inlet manifold 210 using a hose coupling. The outlet can be connected to the outlet control valve 245. The outlet control valve 245 can control a rate of flow of liquid from the cold plate 10t into the outlet manifold 215. The outlet control valve 245 can be connected to the outlet manifold 215 using a hose coupling.

The inlet manifold 210 and the outlet manifold 215 can be arranged or disposed lengthwise in parallel through and along a midsection of the battery pack 260. The inlet manifold 210 and the outlet manifold 215 can form a fluid conveyance. One end of the inlet manifold 210 and one of the outlet manifold 215 can be joined or connected to each other to define a return 220. The inlet manifold 210 and the outlet manifold 215 can additionally or alternatively be connected through the cold plates 105.

The method 400 can include measuring a characteristic of a battery module 125 (ACT 415). The characteristic can be measured by the sensors 255 disposed on or otherwise associated with the battery module 125. The sensor 255 can measure characteristics of the battery block 115 or the submodule 120 of the battery module 125. The characteristics of the battery module 125 can include a temperature from heat emitted by the battery block 115, a pressure exerted from the battery module 125, and detection of gaseous substances released from the battery cells 110 of the battery module 125. The sensor 255 can include a thermometer to measure the temperature, a force meter or a pressure gauge to measure the pressure, and a gas detector. The BMS 205 can retrieve the measurements of the battery module 125 from the sensors 255.

The method 400 can include controlling at least one valve of the cold plate 105 (ACT 420). Using the characteristics measured for each battery module 125, the BMS 205 can determine a target flow rate of coolant into the cold plate 105 thermally coupled with the battery module 125. The BMS 205 can calculate an intake flow rate for the inlet control valve 240 of each cold plate 105 based on the measured characteristics of the battery module 125. The BMS 205 can send a signal to command the inlet control valve 240 of the cold plate 105. The BMS 205 can calculate an outtake flow rate for the outlet control valve 245 of each cold plate 105 also based on the measured characteristics of the battery module 125.

The BMS 205 can send a control signal to command the outlet control valve 245 of the cold plate 105. The control signal can include a command to open or adjust (e.g., increase) a size of an aperture of the inlet or the outlet to achieve the target flow rate. The control signal can include a command to close or adjust (e.g., decrease) a size of an aperture of the inlet or the outlet to achieve the target flow rate. The control signal can include a command to throttle the size of an aperture of the inlet or the outlet to achieve the target flow rate. The control signal can include a command to throttle the size of an aperture of the inlet or the outlet to achieve the target flow rate. The control signal can include a command to maintain or keep constant a size of an aperture of the inlet or the outlet. The control signal can include a command to keep constant a size of an aperture of the inlet or the outlet.

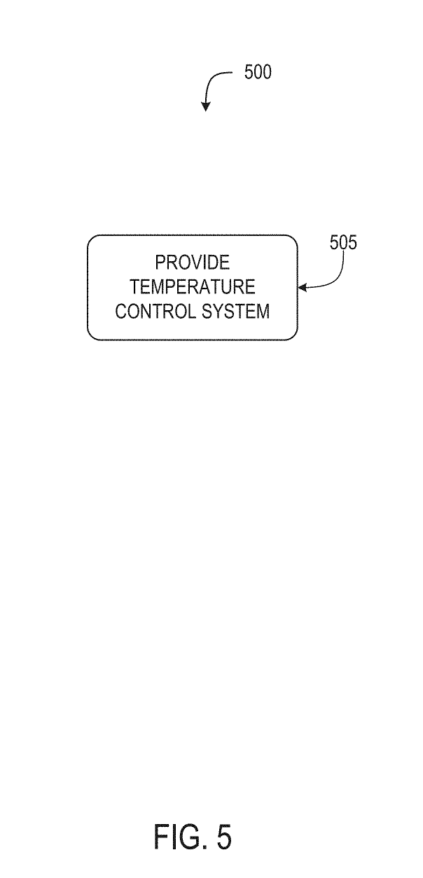

FIG. 5 depicts a flow diagram of a method 500 of controlling temperature in energy storage units. The method 500 can be performed or implemented using the components detailed above in conjunction with FIGS. 1-3 and 6. The method 500 can including providing a temperature control system 100. The temperature control system 100 can be provided to an electric vehicle 300. The temperature control system 100 can include a set of modules 125, each including a set of battery cells 110. The temperature control system 100 can include a set of cold plates 105. Each cold plate 105 can be thermally coupled with one of the battery modules 125. Each cold plate 105 can have an inlet control valve 240 to control a flow rate of coolant into the cold plate 105 from an inlet manifold 210. Each cold plate 105 can have an outlet control valve 245 to control a flow rate of liquid released from the cold plate 105 to an outlet manifold 215. The system 100 can include one or more sensors 255 to measure temperature and other characteristics of the modules 125 thermally coupled with the cold plates 105. The system 100 can include a battery management system (BMS) 205 to send control signals to each inlet control valve 240 and each outlet control valve 245 based on the measured temperature of the module 125 thermally coupled with the cold plate 105. Using the measured temperature, the BMS 205 can set or determine a target intake flow rate and an outtake flow rate for each of the cold plates 105. The BMS 205 can send a control signal to control the inlet control valves 240 and the outlet control valves 245. The control signal can include a command to open to an aperture of the inlet control valve 240 to a specified size. The control signal can include a command to close to an aperture of the outlet control valve 245 to a specified size.

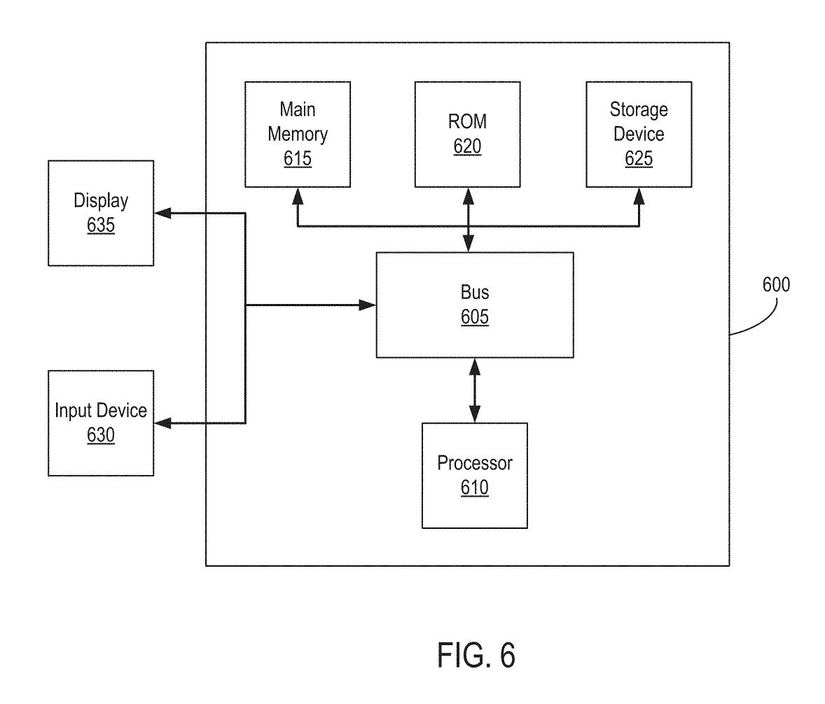

FIG. 6 depicts a block diagram of an example computer system 600. The computer system or computing device 600 can include or be used to implement the BMU 135 or BMS 205. The computing system 600 includes at least one bus 605 or other communication component for communicating information and at least one processor 610 or processing circuit coupled to the bus 605 for processing information. The computing system 600 can also include one or more processors 610 or processing circuits coupled to the bus for processing information. The computing system 600 also includes at least one main memory 615, such as a random access memory (RAM) or other dynamic storage device, coupled to the bus 605 for storing information, and instructions to be executed by the processor 610. The main memory 615 can be or include the BMU 135 or BMS 205. The main memory 615 can also be used for storing position information, vehicle information, command instructions, vehicle status information, environmental information within or external to the vehicle, road status or road condition information, or other information during execution of instructions by the processor 610. The computing system 600 may further include at least one read only memory (ROM) 620 or other static storage device coupled to the bus 605 for storing static information and instructions for the processor 610. A storage device 625, such as a solid state device, magnetic disk or optical disk, can be coupled to the bus 605 to persistently store information and instructions. The storage device 625 can include or be part of the BMU 135 or BMS 205.

The computing system 600 may be coupled via the bus 605 to a display 635, such as a liquid crystal display, or active matrix display, for displaying information to a user such as a driver of the electric vehicle 300. An input device 630, such as a keyboard or voice interface may be coupled to the bus 605 for communicating information and commands to the processor 610. The input device 630 can include a touch screen display 635. The input device 630 can also include a cursor control, such as a mouse, a trackball, or cursor direction keys, for communicating direction information and command selections to the processor 610 and for controlling cursor movement on the display 635. The display 635 can be coupled with the BMU 135 or BMS 205 to display various diagnostic data regarding the system 200.

The processes, systems and methods described herein can be implemented by the computing system 600 in response to the processor 610 executing an arrangement of instructions contained in main memory 615. Such instructions can be read into main memory 615 from another computer-readable medium, such as the storage device 625. Execution of the arrangement of instructions contained in main memory 615 causes the computing system 600 to perform the illustrative processes described herein. One or more processors in a multi-processing arrangement may also be employed to execute the instructions contained in main memory 615. Hard-wired circuitry can be used in place of or in combination with software instructions together with the systems and methods described herein. Systems and methods described herein are not limited to any specific combination of hardware circuitry and software.

Although an example computing system has been described in FIG. 6, the subject matter including the operations described in this specification can be implemented in other types of digital electronic circuitry, or in computer software, firmware, or hardware, including the structures disclosed in this specification and their structural equivalents, or in combinations of one or more of them.

While operations may be depicted in the drawings or described in a particular order, such operations are not required to be performed in the particular order shown or described, or in sequential order, and all depicted or described operations are not required to be performed. Actions described herein can be performed in different orders.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. Further, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

What is claimed is:

1. A system to control temperature in energy storage units in electric vehicles, comprising:
a plurality of energy storage units disposed in an electric vehicle to power the electric vehicle;
a plurality of cold plates disposed in the electric vehicle and connected in parallel to an inlet manifold and an outlet manifold, each cold plate thermally coupled with an energy storage unit of the plurality of energy storage units to transfer heat away from the energy storage unit using a coolant, each cold plate having:
an inlet to receive the coolant from the inlet manifold to enter the cold plate;
an outlet to release liquid from the cold plate to the outlet manifold; and
at least one control valve coupled to at least one of the inlet and the outlet; and
a battery management system (BMS) connected with the plurality of energy storage units and to the at least one control valve of each of the plurality of cold plates to:
receive, from each energy storage unit, an input signal indicative of a characteristic of the energy storage unit;
determine, for each cold plate, a target flow rate for the coolant through at least one of the inlet and the outlet in accordance with the characteristic of the energy storage unit thermally coupled with the cold plate; and
send, to each cold plate, at least one control signal to control the at least one control valve of the cold plate in accordance with the target flow rate of the coolant determined for the cold plate.

2. The system of claim 1, comprising:
the BMS to:
determine, for each cold plate, at least one of a target intake flow rate of the coolant and a target outtake flow rate of the coolant based on the characteristic of the energy storage unit thermally coupled with the cold plate; and
send, to each cold plate, the at least one control signal to control the at least one control valve to make an adjustment to the at least one of the target intake flow rate and the target outtake flow rate.

3. The system of claim 1, comprising:
the BMS to:
determine, for each energy storage unit, a deviation measure from a defined operational value or range, based at least in part on the characteristic indicated by the input signal; and
determine, for each cold plate, the target flow rate for the coolant through at least one of the inlet and the outlet based at least in part on the deviation measure for the energy storage unit thermally coupled to the cold plate.

4. The system of claim 1, comprising:
the BMS to:
determine, for each energy storage unit, a risk metric of a failure event based at least in part on the characteristic of the energy storage unit indicated by the input signal; and
determine, for each cold plate, the target flow rate for the coolant through at least one of the inlet and the outlet based at least in part on the risk metric of the failure event for the energy storage unit thermally coupled to the cold plate.

5. The system of claim 1, wherein the input signal is indicative of a temperature of the energy storage unit, the temperature measured using at least one of a thermistor for the energy storage unit and a temperature sensor on the at least one valve.

6. The system of claim 1, wherein the input signal is indicative of a gas released from the energy storage unit, and detected by a sensor communicatively coupled with the BMS.

7. The system of claim 1, wherein the input signal is indicative of a pressure exerted from the energy storage unit and measured using a gauge coupled with the BMS.

8. The system of claim 1, comprising:
the BMS to send, to each cold plate, the at least one control signal to control the at least one control valve of the cold plate, the at least one control signal including at least one of: an open command to open the at least one valve to adjust a size of aperture of the at least one control valve, a close command to close the at least one valve to adjust a size of the aperture of the at least one control valve, a maintain command to maintain the flow rate through the at least one valve, and a throttle command to open and close the at least one valve at a specified rate.

9. The system of claim 1, comprising:
each cold plate of the plurality of cold plates having:
an inlet temperature sensor to measure a temperature of the coolant entering into the cold plate via the inlet; and
an outlet temperature sensor to measure a temperature of the liquid released from the cold plate via the outlet; and
the BMS to:
determine, for each cold plate, a temperature difference between the temperature measured by the inlet temperature sensor and the temperature measured by the outlet temperature sensor; and
determine, for each cold plate, at least one of a target intake flow rate of the coolant and a target outtake flow rate of the liquid based on at least the temperature difference for the cold plate.

10. The system of claim 1, comprising:
the BMS to:
identify a failure event occurring in a cold plate from the plurality of cold plates according to the characteristic of the energy storage unit thermally coupled with the cold plate; and
send, responsive to the failure event occurring in the cold plate, the control signal to control the at least one control valve to decrease the flow rate of the coolant released from the cold plate via the outlet.

11. The system of claim 1, comprising:
the at least one control valve of each cold plate of the plurality of cold plates, having:
an inlet control valve to control an intake flow rate of the coolant into the cold plate by translating the target flow rate to a movement of a restrictive member within the inlet; and
an outlet control valve to control an outtake flow rate of the liquid released from the cold plate by translating the target flow rate to a movement of a restrictive member within the outlet.

12. The system of claim 1, comprising:
the inlet manifold and the outlet manifold extending along a midsection of the plurality of energy storage units between the plurality of cold plates.

13. The system of claim 1, comprising:
a return conduit connecting one end of the inlet manifold with one end of the outlet manifold.

14. The system of claim 1, comprising:
the plurality of cold plates arranged coplanar relative to one another within the electric vehicle below the plurality of energy storage units.

15. A method of controlling temperature in energy storage units in electric vehicles, comprising:
providing a temperature control system in an electric vehicle, comprising:
a plurality of energy storage units disposed in the electric vehicle to power the electric vehicle;
a plurality of cold plates disposed in the electric vehicle and connected in parallel to an inlet manifold and an outlet manifold, each cold plate thermally coupled with an energy storage unit of the plurality of energy storage units to transfer heat away from the energy storage unit using a coolant, each cold plate having:
an inlet to receive the coolant from the inlet manifold to enter the cold plate;
an outlet to release liquid from the cold plate to the outlet manifold; and
at least one control valve coupled to at least one of the inlet and the outlet; and
a battery management system (BMS) connected with the plurality of energy storage units and to the at least one control valve of each of the plurality of cold plates to:
receive, from each energy storage unit, an input signal indicative of a characteristic of the energy storage unit;
determine, for each cold plate, a target flow rate for the coolant through at least one of the inlet and the outlet in accordance with the characteristic of the energy storage unit thermally coupled with the cold plate; and
send, to each cold plate, at least one control signal to control the at least one control valve of the cold plate in accordance with the target flow rate of the coolant determined for the cold plate.

16. The method of claim 15, comprising:
providing the temperature control system, comprising:
the BMS to:
determine, for each cold plate, an intake flow rate of the coolant and an outtake flow rate of the liquid based on the characteristic measured for the energy storage unit thermally coupled with the cold plate; and
send, to each cold plate, the at least one control signal to control the at least one control valve in accordance with the intake flow rate and the outtake flow rate.

17. The method of claim 15, comprising:
providing the temperature control system, comprising: the inlet manifold and the outlet manifold extending along a midsection of the plurality of energy storage units between the plurality of cold plates.

18. An electric vehicle, comprising:
one or more components;
a plurality of energy storage units connected in parallel to an inlet manifold and an outlet manifold and disposed to power the one or more components;
a plurality of cold plates, each cold plate thermally coupled with an energy storage unit of the plurality of energy storage units to transfer heat away from the energy storage unit using a coolant, each cold plate having:
an inlet to receive the coolant from the inlet manifold to enter the cold plate;
an outlet to release liquid from the cold plate to the outlet manifold; and
at least one control valve coupled to at least one of the inlet and the outlet; and
a battery management system (BMS) connected with the plurality of energy storage units and to the at least one control valve of each of the plurality of cold plates to:
receive, from each energy storage unit, an input signal indicative of a characteristic of the energy storage unit;
determine, for each cold plate, a target flow rate for the coolant through at least one of the inlet and the outlet in accordance with the characteristic of the energy storage unit thermally coupled with the cold plate; and
send, to each cold plate, at least one control signal to control the at least one control valve of the cold plate in accordance with the flow rate of the coolant determined for the cold plate.

19. The electric vehicle of claim 18, comprising:
the BMS to:
determine, for each cold plate, an intake flow rate of the coolant and an outtake flow rate of the liquid based on the characteristic measured for the energy storage unit thermally coupled with the cold plate; and
send, to each cold plate, the at least one control signal to control the at least one control valve in accordance with the intake flow rate and the outtake flow rate.

20. The electric vehicle of claim 18, comprising:
the inlet manifold and the outlet manifold extending along a midsection of the plurality of energy storage units between the plurality of cold plates.
